(19) United States
(12) Patent Application Publication
(10) Pub. No.: US 2026/0242943 A1
(43) Pub. Date: Aug. 20, 2026

(54) METHOD OF PROCESSING SUBSTRATE, METHOD OF MANUFACTURING SEMICONDUCTOR DEVICE, SUBSTRATE PROCESSING APPARATUS AND RECORDING MEDIUM

(71) Applicant: Kokusai Electric Corporation, Tokyo (JP)

(72) Inventors: Nagisa SUYAMA, Toyama-shi (JP); Hiroyuki KOIDE, Toyama-shi (JP); Shota TANAKA, Toyama-shi (JP)

(73) Assignee: Kokusai Electric Corporation, Tokyo (JP)

(21) Appl. No.: 19/642,819

(22) Filed: Apr. 9, 2026

Related U.S. Application Data
(63) Continuation of application No. PCT/JP2024/037259, filed on Oct. 18, 2024.

(30) Foreign Application Priority Data
Mar. 26, 2024 (JP) 2024-049402

(51) Int. Cl. C23C 16/455

(52) U.S. Cl. CPC C23C 16/45523

(57) ABSTRACT

A technique includes: forming a film of a predetermined substance containing a first element by performing a cycle a predetermined number of times, the cycle including: (a1) supplying, under a predetermined condition, a first gas to a substrate, which includes a recess on a surface, to deposit a first substance containing the first element on the surface, wherein the predetermined condition satisfies: a temperature condition that a substrate temperature is equal to or higher than a decomposition temperature of the first gas, and a first condition that an amount of the first substance adsorbed on an opening portion of the recess increases during a first period after starting supplying the first gas, the amount gradually approaches a predetermined value during a second period after the first period, and the amount increases during a third period after the second period, and wherein (a1) is ended during the second period.

### CROSS-REFERENCE TO RELATED APPLICATION

This application is a Bypass Continuation Application of PCT International Application No. PCT/JP2024/037259, filed on October 18, 2024, and designating9 the United States, the international application being based upon and claiming the benefit of priority from Japanese Patent Application No. 2024-049402, filed on March 26, 2024, the entire content of which is incorporated herein by reference.

### TECHNICAL FIELD

The present disclosure relates to a method of processing a substrate, a method of manufacturing a semiconductor device, a substrate processing apparatus, and a recording medium.

### BACKGROUND

In the related art, when supplying a gas to a substrate, the substrate may be processed by setting a temperature of the substrate to a gas decomposition temperature or higher.

### SUMMARY

Some embodiments of the present disclosure provide a technique capable of improving at least one selected from the group of step coverage and film properties.

According to some embodiments of the present disclosure, there is provided a technique that includes: forming a film of a predetermined substance containing a first element by performing a cycle a predetermined number of times, the cycle including: (a1) supplying, under a predetermined condition, a first gas to a substrate, which includes a recess on a surface of the substrate to deposit a first substance containing the first element on the surface of the substrate, wherein the predetermined condition satisfies: a temperature condition that a temperature of the substrate is set to be equal to or higher than a decomposition temperature of the first gas, and a first condition that an opening portion adsorption amount, which is an amount of the first substance adsorbed on an opening portion of the recess, increases during a first period after a start of the supply of the first gas, the opening portion adsorption amount gradually approaches a predetermined value during a second period after the first period, and the opening portion adsorption amount increases during a third period after the second period, and wherein (a1) is ended during the second period.

### BRIEF DESCRIPTION OF DRAWINGS

The accompanying drawings, which are incorporated in and constitute a part of the specification, illustrate embodiments of the present disclosure.

FIG. 1 is a vertical cross-sectional view schematically showing a substrate processing apparatus according to some embodiments of the present disclosure.

FIG. 2A is a diagram showing a first gas supply system according to some embodiments of the present disclosure. FIG. 2B is a view showing a second gas supply system according to some embodiments of the present disclosure. FIG. 2C is a view showing an exhaust system according to some embodiments of the present disclosure.

FIG. 3 is a schematic configuration diagram of a controller of the substrate processing apparatus according to some embodiments of the present disclosure, in which a control system of the controller is shown in a block diagram.

FIG. 4 is a schematic diagram of a vertical cross-section of a recess formed on a substrate according to some embodiments of the present disclosure.

FIG. 5A is a schematic diagram showing a time-dependent change in an opening portion adsorption amount Aₜₒₚ according to some embodiments of the present disclosure. FIG. 5B is a schematic diagram showing a time-dependent change in a deep portion adsorption amount A_{btm} according to some embodiments of the present disclosure.

FIG. 6A is a diagram schematically showing a change in a decomposition rate of a first gas in a process chamber over time from a start of supply of the first gas according to some embodiments of the present disclosure. FIG. 6B is a diagram schematically showing a change in a flow velocity of the first gas in the process chamber over time from the start of the supply of the first gas according to some embodiments of the present disclosure. FIG. 6C is a diagram schematically showing a change in a pressure inside the process chamber over time from the start of the supply of the first gas according to some embodiments of the present disclosure.

FIG. 7A is a flowchart of a substrate processing process according to some embodiments of the present disclosure. FIG. 7B is a flowchart of a processing process according to some embodiments of the present disclosure. FIG. 7C is a flowchart of a first gas supply process according to some embodiments of the present disclosure. FIG. 7D is a flowchart of a preparation process according to some embodiments of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

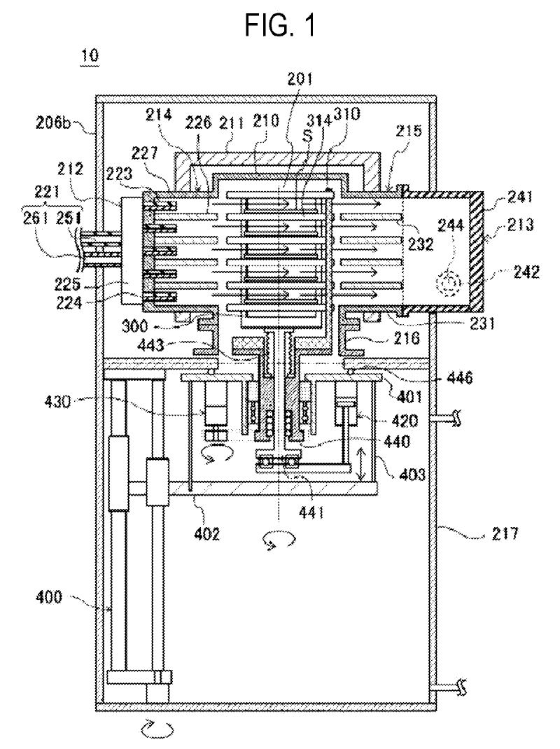

Some embodiments of the present disclosure are described mainly with reference to FIGS. 1, 2A to 2C, 3, 4, 5A, 5B, 6A to 6C , and 7A to 7D. Drawings used in the following description are schematic, and dimensional relationships between respective elements, proportions of respective elements, and the like shown in the drawings may not match actual ones. In addition, dimensional relationships between respective elements, proportions of respective elements, and the like may not match among multiple drawings.

### 1 Configuration of Substrate Processing Apparatus

A configuration of a substrate processing apparatus 10 is described with reference to FIG. 1.

The substrate processing apparatus 10 includes a reaction tube storage chamber 206b. The reaction tube storage chamber 206b is installed with a reaction tube 210, a heater 211 as a heating part (a furnace and a temperature controller) provided around the reaction tube 210, a gas supply structure 212 as a gas supplier, and a gas exhaust structure 213 as a gas exhaust. The gas supplier may include an upstream gas guide 214 and nozzles 223 and 224, which are described later. Further, the gas exhaust may include a downstream gas guide 215, which is described later. A section of the reaction tube 210 where substrates S are processed is referred to as a process chamber 201. The process chamber 201 may also be referred to as a process space in which the substrates S are disposed.

A gas supplied from the gas supply structure 212 into the reaction tube 210 moves horizontally relative to the substrates S and is discharged from the gas exhaust structure 213. An upstream gas guide 214 is provided between the reaction tube 210 and the gas supply structure 212. A downstream gas guide 215 is provided between the reaction tube 210 and the gas exhaust structure 213. A lower end of the reaction tube 210 is supported by a manifold 216. Heat generated from the heater 211 heats the substrates S or a gas in the process chamber 201.

The gas supply structure 212 is connected to a gas supply pipe 251 and a gas supply pipe 261 and includes a distributor 225 that distributes a gas supplied from each gas supply pipe. A plurality of nozzles 223 and 224 are provided downstream of the distributor 225. In the embodiments, the gas supply pipe 251 and the gas supply pipe 261 are collectively referred to as gas supply pipes 221. Each nozzle is also referred to as a gas discharger. The distributor 225 is configured to supply each gas from the gas supply pipe 251 to the nozzle 223 and from the gas supply pipe 261 to the nozzle 224. The upstream gas guide 214 includes a housing 227 and divider plates 226. The nozzles 223 and 224 are provided between the divider plates 226 or between the divider plate 226 and the housing 227. The downstream gas guide 215 includes a housing 231 and divider plates 232. The gas exhaust structure 213 mainly includes a housing 241, an exhaust pipe connector 242, and an exhaust hole 244.

A delivery chamber 217 is formed at a lower portion of the reaction tube 210. Inside the delivery chamber 217, a transfer robot (not shown) transfers the substrates S between an inside and an outside of the delivery chamber 217 through a substrate loading port (not shown), and charges and discharges the substrates S onto and from a substrate support 300 (hereinafter sometimes simply referred to as a boat) inside the delivery chamber 217.

A vertical drive 400 moves the substrate support 300 and the partition plate support 310 up and down between the reaction tube 210 and the delivery chamber 217. FIG. 1 shows a state in which the substrate support 300 and the partition plate support 310 are raised by the vertical drive 400 and stored in the reaction tube 210. The vertical drive 400 includes a rotary drive 430 that rotates the substrate support 300 and the partition plate support 310 together, and a boat vertical drive 420 that drives the substrate support 300 up and down relative to the partition plate support 310. The rotary drive 430 and the boat vertical drive 420 are fixed to a base flange 401 serving as a lid, which is supported on a base plate 402 by a side plate 403. An O-ring 446 for vacuum sealing is provided on an upper surface of the base flange 401. A support 440 fixed to the partition plate support 310 and a support 441 fixed to the substrate support 300 are connected by a vacuum bellows 443.

A plurality of substrates S are mounted on the substrate support 300 at predetermined intervals in a vertical direction (perpendicular direction). A plurality of partition plates 314 disposed on the partition plate support 310 are located directly under the substrates S and above and/or below the substrates S. In a substrate processing process described below, it is desirable to align heights of the partition plates 314 with those of the divider plates 226 and 232. This makes it easier to form a horizontal gas flow on the divider plate 226, the substrate S and the divider plate 232 while suppressing a vertical flow, which makes it possible to uniformly process the respective substrates S.

FIG. 1 shows an example in which five substrates S are supported on the substrate support 300. However, the present disclosure is not limited thereto. The substrate support 300 may be configured to support, for example, 5 to 50 substrates S. As used herein, the expression of a numerical range such as "5 to 50 substrates" means that the lower limit and upper limit are included in the range. Therefore, for example, "5 to 50 substrates" means "5 or more and 50 or less substrates." The same applies to other numerical ranges.

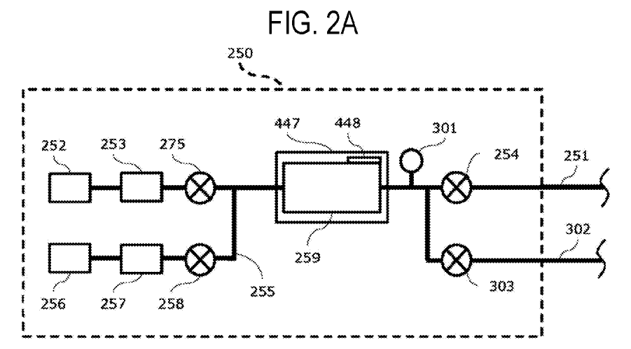

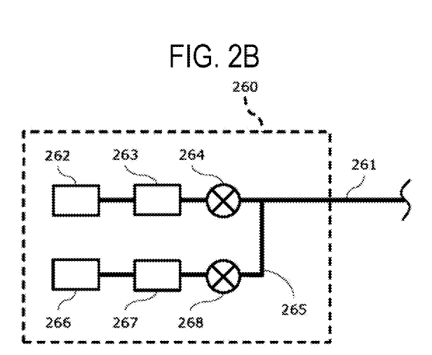

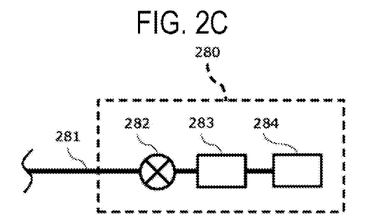

As shown in FIG. 2A, on the gas supply pipe 251, a first gas source 252, a mass flow controller (MFC) 253, which is a flow rate controller (flow rate control part), a valve 275, which is an on-off valve, a tank 259, which is a storage that stores a gas therein, a sensor 301, which is a pressure measurer (pressure measurement part) that measures a pressure inside the tank 259, and a valve 254 are installed sequentially from an upstream direction.

The tank 259 is installed with a sensor 448, which is a temperature measurer (temperature measurement part) that measures a temperature of the tank 259 and/or a temperature of a gas stored in the tank 259. The tank 259 is also installed with a heater 447, which is a temperature controller (temperature control part) that adjusts the temperature of the tank 259 and/or the temperature of the gas stored in the tank 259. Instead of installing the tank 259, the gas supply pipe 251 between the valve 275 upstream of the tank 259 and the valve 254 downstream of the tank 259 may be increased in diameter or formed in a spiral shape to increase capacity, and may be used as a storage. By opening and closing the valve 275 upstream of the tank 259 and the valve 254 downstream of the tank 259, a gas supplied from the gas supply pipe 251 may be temporarily stored (filled) in the tank 259, or the gas stored in the tank 259 may be supplied into the process chamber 201.

The first gas source 252 is a gas source that supplies a first gas (also referred to as a precursor gas). Alternatively, a vaporizer that generates the first gas by vaporizing a liquid or a solid may be used as the first gas source 252. Hereinafter, a case in which a gas obtained by vaporizing a liquid or a solid is used as the first gas is described by way of example.

A first gas supply system 250 (also referred to as a precursor gas supply system) mainly includes the gas supply pipe 251, the MFC 253, the valve 275, the tank 259, the sensor 301, and the valve 254. The first gas supply system 250 may include the first gas source 252. The first gas supply system 250 may also include the sensor 448 and the heater 447. In addition to the heater 447, heaters (not shown) may be provided in various parts of the first gas supply system 250 to regulate a temperature of the first gas supply system 250. The first gas supply system 250 is an example of a gas supply system that stores the first gas in the tank 259 and supplies the first gas stored in the tank 259 to the substrates S.

A gas exhaust pipe 302 that discharges the gas in the tank 259 to an outside of the process chamber 201 without supplying the gas to the process chamber 201 is connected to the gas supply pipe 251 between the sensor 301 and the valve 254. A valve 303 is installed on the gas exhaust pipe 302. A first gas exhaust system (also referred to as a precursor gas exhaust system) mainly includes the gas exhaust pipe 302 and the valve 303. The first gas exhaust system may be included in the first gas supply system 250.

A gas supply pipe 255 is connected to the gas supply pipe 251 between the valve 275 and the tank 259. On the gas supply pipe 255, an inert gas source 256, a MFC 257, and a valve 258 are installed sequentially from an upstream direction. An inert gas is supplied from the inert gas source 256. A first inert gas supply system mainly includes the gas supply pipe 255, the MFC 257, and the valve 258. The inert gas source 256 may be included in the first inert gas supply system. The first inert gas supply system may be included in the first gas supply system 250.

As shown in FIG. 2B, on the gas supply pipe 261, a second gas source 262, a MFC 263, and a valve 264 are installed sequentially from an upstream direction. The second gas source 262 is a gas source that supplies a second gas (also referred to as a reaction gas). A second gas supply system 260 (also referred to as a reaction gas supply system) mainly includes the gas supply pipe 261, the MFC 263, and the valve 264. The second gas source 262 may be included in the second gas supply system 260.

A gas supply pipe 265 is connected to the gas supply pipe 261 on a downstream side of the valve 264. On the gas supply pipe 265, an inert gas source 266, a MFC 267, and a valve 268 are installed sequentially from an upstream direction. An inert gas is supplied from the inert gas source 266. A second inert gas supply system mainly includes the gas supply pipe 265, the MFC 267, and the valve 268. The inert gas source 266 may be included in the second inert gas supply system. The second inert gas supply system may be included in the second gas supply system 260.

As shown in FIG. 2C, a vacuum pump 284 serving as a vacuum exhauster is connected to the exhaust pipe 281 via a valve 282 and an auto pressure controller (APC) valve 283 serving as a pressure regulator (pressure regulating part), and is configured to be capable of vacuum-exhausting the reaction tube 210 so that a pressure inside the reaction tube 210 becomes a predetermined pressure (degree of vacuum). The exhaust pipe 281 is connected to an exhaust pipe connector 242. The exhaust pipe 281, the valve 282, and the APC valve 283 are collectively referred to as an exhaust system 280. The exhaust system 280 is also referred to as a process chamber exhaust system. The vacuum pump 284 may be included in the exhaust system 280.

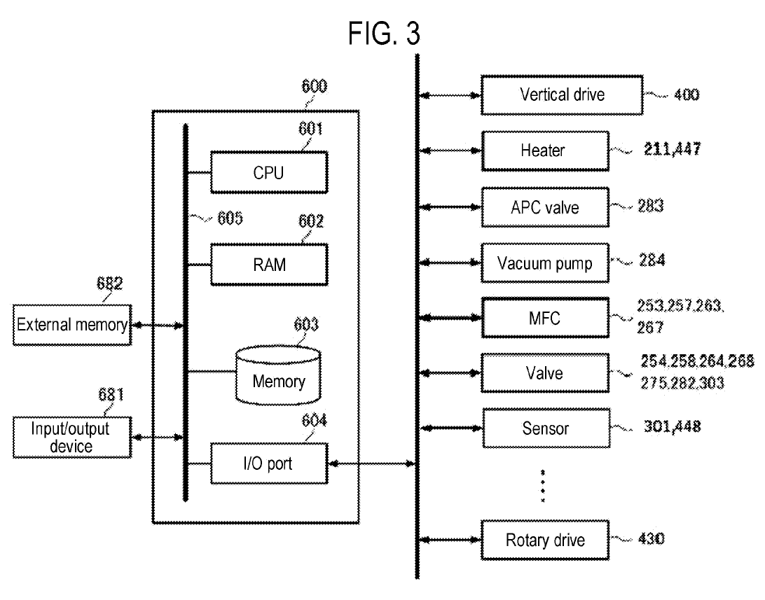

Next, a controller which is a control part (control means) is described with reference to FIG. 3. The substrate processing apparatus 10 includes a controller 600 that controls an operation of each part of the substrate processing apparatus 10.

An outline of the controller 600 is shown in FIG. 3. The controller 600 is configured as a computer including a central processing unit (CPU) 601, a random access memory (RAM) 602, a memory 603 as a memory part, and an I/O port 604. The RAM 602, the memory 603, and the I/O port 604 are configured to be capable of exchanging data with the CPU 601 via an internal bus 605.

The memory 603 includes, for example, a flash memory, a hard disk drive (HDD), or the like. A control program that controls an operation of the substrate processing apparatus 10, a process recipe in which procedures or conditions of substrate processing are written, and the like are readably recorded and stored in the memory 603. Meanwhile, the process recipe is a combination that executes each procedure in the substrate processing process to be described later in the controller 600 so as to obtain a predetermined result, and functions as a program. Hereinafter, the process recipe, the control program, and the like are collectively simply referred to as a program (program product). As used herein, the term "program" may refer to a case of solely including the process recipe, a case of solely including the control program, or a case of including both. In addition, the RAM 602 is configured as a memory area (work area) in which programs, data, and the like read by the CPU 601 are temporarily held.

The I/O port 604 is connected to the above-described vertical drive 400, the heaters 211 and 447, the APC valve 283, the vacuum pump 284, the MFCs 253, 257, 263 and 267, the valves 254, 258, 264, 268, 275, 282 and 303, the sensors 301 and 448, the rotary drive 430, and others.

The CPU 601 is configured to read and execute the control program from the memory 603, and is also configured to read the process recipe from the memory 603 in response to an input of an operation command from the input/output device 681 or the like. The CPU 601 is configured to control, in accordance with contents of the process recipe thus read, a raising/lowering operation of the substrate support 300 by the vertical drive 400, a heating operation by the heater 211, a regulating operation of an opening degree of the APC valve 283, start and stop of the vacuum pump 284, flow rate regulating operations for various gases by the MFCs 253, 257, 263 and 267, opening/closing operations of the valves 254, 258, 264, 268, 275, 282 and 303, a measuring operation of the pressure in the tank 259 by the sensor 301, a temperature measuring operation for the tank 259 and/or the gas stored in the tank 259 by the sensor 448, a temperature controlling operation for the tank 259 and/or the gas stored in the tank 259 by the heater 447, rotation and rotation speed adjusting operation of the substrate support 300 by the rotary drive 430, and so on. The MFCs 253, 257, 263 and 267, the valves 254, 258, 264, 268, 275, 282 and 303, the APC valve 283, and the vacuum pump 284 may be used as a gas controller configured to be capable of controlling supply and exhaust of a gas into and out of the process chamber 201.

The controller 600 according to the embodiments may be configured by installing the above-mentioned program into a computer using an external memory 682 (e.g., a magnetic disk such as a hard disk, an optical disk such as a DVD, a magneto-optical disk such as a MO, or a semiconductor memory such as a USB memory) that records and stores the program. Meanwhile, a means for supplying the program to the computer is not limited to supplying the program via the external memory 682. For example, the program may be supplied via a communication means such as the Internet or a dedicated line without going through the external memory 682. The memory 603 and the external memory 682 are configured as computer-readable recording media on which the program is recorded. Hereinafter, the memory 603 and the external memory 682 are collectively simply referred to as a recording medium. As used herein, the term "recording medium" may refer to a case of solely including the memory 603, a case of solely including the external memory 682, or a case of including both.

### 2 Substrate Processing Process

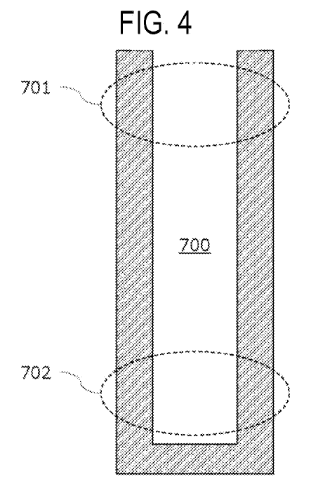

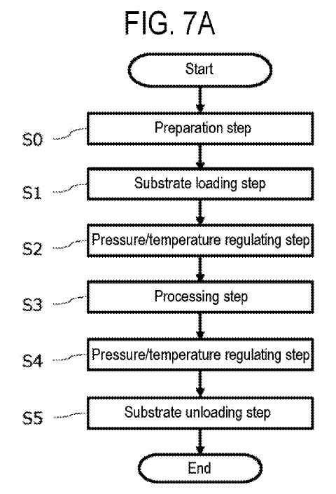

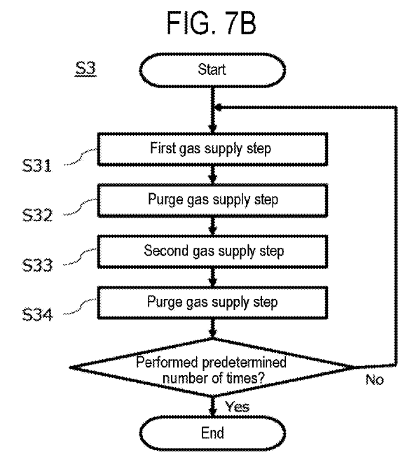

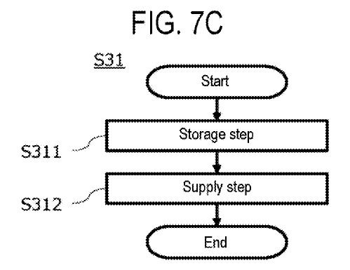

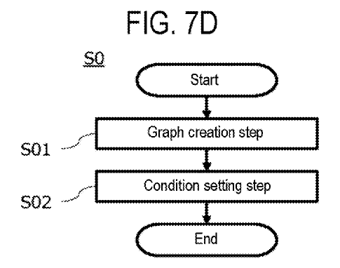

Next, as a process of manufacturing a semiconductor device, a substrate processing process for forming a thin film on a substrate S by using the substrate processing apparatus 10 configured as above is described with reference to FIG. 4 and FIGS. 7A through 7D.

As shown in FIG. 4, a recess 700 such as a trench or a hole is formed on a surface of the substrate S. In the following description, an opening portion 701 of the recess 700 is also simply referred to as an opening portion 701, and a deep portion 702 of the recess 700 is also simply referred to as a deep portion 702.

As shown in FIG. 7A, the substrate processing process includes a preparation step S0, a substrate loading step S1, a pressure/temperature regulating step S2, a processing step S3, a pressure/temperature regulating step S4, and a substrate unloading step S5. In the following description, the operation of each part constituting the substrate processing apparatus 10 is controlled by the controller 600. Since the preparation step S0 may be omitted, the following description begins with description of the substrate loading step S1, and the preparation step S0 is described later.

The term "substrate" as used herein may refer to a substrate itself or to a stacked body of a substrate and a predetermined layer or film formed on a surface of the substrate. The term "a surface of a substrate" as used herein may refer to a surface of a substrate itself or a surface of a predetermined layer or the like formed on a substrate. The expression "forming a predetermined layer on a substrate" as used herein may mean forming a predetermined layer directly on a surface of a substrate itself or forming a predetermined layer on a layer or the like formed on a substrate. The term "wafer" as used herein is synonymous with the term "substrate."

### Substrate Loading Step S1

In the delivery chamber 217, a plurality of substrates S are charged onto the substrate support 300 (wafer charging). Then, the substrate support 300 is raised by the vertical drive 400, and the substrates S are loaded into the reaction tube 210, i.e., the process chamber 201 (boat loading).

### Pressure/Temperature Regulating Step S2

The opening degree of the APC valve 283 is regulated and the process chamber 201 is vacuum-exhausted by the vacuum pump 284 so that the pressure inside the process chamber 201 becomes a desired pressure (pressure regulation). Further, an output of the heater 211 is controlled so that a temperature inside the process chamber 201 or a temperature of the substrate S becomes a desired temperature (temperature regulation). In other words, the pressure/temperature regulating step S2 is a step of regulating at least one selected from the group of the temperature and the pressure inside the process chamber 201. Further, the rotary drive 430 rotates the substrate support 300 (and the substrates S) and the partition plate support 310. In addition, the tank 259 is heated by the heater 447 so that the temperature of the tank 259 or the temperature of the gas inside the tank 259 becomes a desired temperature (tank temperature regulation).

At this time, the temperature of the first gas supply system 250 is controlled so that a temperature of the first gas supplied from the first gas source 252 into the tank 259 is lower than the temperature of the tank 259 or the first gas existing inside the tank 259. This makes it possible to suppress generation of particles caused by liquefaction or solidification of a portion of the first gas inside the tank 259. These operations are continued at least until the processing of the substrate S is completed.

### Processing Step S3

Next, as shown in FIG. 7B, a processing cycle including a first gas supply step S31, a purge gas supply step S32, a second gas supply step S33 and a purge gas supply step S34 is performed a predetermined number of times (n times where n is 1 or an integer of 2 or more). In the following description, a case in which the processing step S3 is performed under a predetermined condition that satisfies a temperature condition that sets the temperature of the substrate S (and the process chamber 201) to be equal to or higher than the decomposition temperature of the first gas and satisfies first to third conditions described below is described by way of example. As shown in FIG. 7B, in the processing step S3, the first gas supply step S31, the purge gas supply step S32, the second gas supply step S33, and the purge gas supply step S34 are performed.

### First Gas Supply Step S31

As shown in FIG. 7C, in the first gas supply step S31, the first gas is stored in the tank 259 in a storage step S311, and the first gas stored in the tank 259 is supplied into the process chamber 201 (or the substrates S) in a supply step S312. Thus, a layer of a first substance containing a first element (first layer) is formed on the surface of the substrate S. As shown in FIG. 7C, in the first gas supply step S31, the storage step S311 and the supply step S312 are performed.

### Storage Step S311

The storage step S311 is a step of storing the first gas in tank 259. With the valves 254, 258, 303, 264 and 268 closed, the valve 275 is opened to start storing the first gas in the tank 259. Then, after a predetermined time is elapsed, the valve 275 is closed to end the storage step S311.

The storage step S311 in a first processing cycle may be performed partially simultaneously with the substrate loading step S1 and the pressure/temperature regulating step S2. When the processing cycle is performed multiple times, the storage step S311 in a second processing cycle or subsequent processing cycles may be performed partially simultaneously with at least one selected from the group of the purge gas supply step S32, the second gas supply step S33, and the purge gas supply step S34. This makes it possible to improve throughput.

### Supply Step S312

In the supply step S312, the first gas is supplied to the substrates S under the predetermined condition. Specifically, the valve 254 is opened while closing the valves 258, 275, 303, 264 and 268, and at least a portion of the first gas stored (filled) in the tank 259 is supplied (allowed to flow). Thus, at least a portion of the first gas is supplied to the substrates S in the process chamber 201 at once. By supplying the first gas to the substrates S, it is possible to form the layer of the first substance containing the first element (first layer) on the surface of the substrate S. The supply step S312 is ended by closing the valve 254 after a predetermined time is elapsed since a start of the supply of the first gas.

In this case, it is desirable to perform the supply step S312 such that a predetermined amount X of the first gas remains in the tank 259 at an end of the supply step S312. The predetermined amount X may be set to any value between 0.1 and 99 % of an amount (predetermined amount Y) of the first gas stored in the tank 259 at a start of the supply step S312. At this time, the supply step S312 may be ended when the pressure in the tank 259 measured by the sensor 301 drops to a predetermined pressure. Also, the predetermined pressure may be regulated to control the amount of the first gas remaining in the tank 259 at the end of the supply step S312.

Meanwhile, in the supply step S312, the valve 258 may be opened to supply an inert gas into the gas supply pipe 251 via the gas supply pipe 255. Further, in order to prevent the first gas from entering the gas supply pipe 261, the valves 268 and 264 may be opened to supply the inert gas into the gas supply pipe 261. In addition, for the reasons described below, it is desirable to keep the valve 282 and the APC valve 283 opened in the supply step S312. This increases a flow velocity of the first gas in the process chamber 201, thereby suppressing decomposition of the first gas. Accordingly, it is possible to prolong a second period T₂.

### Purge Gas Supply Step S32

In the purge gas supply step S32, the process chamber 201 is purged. Specifically, while keeping the valves 275, 303 and 264 closed, the valves 254, 258 and 268 are opened to supply an inert gas as a purge gas into the process chamber 201, and the inert gas is exhausted by the vacuum pump 284.

### Second Gas Supply Step S33

In the second gas supply step S33, while keeping the valves 254, 258, 275, 303 and 268 closed, the valve 264 is opened. After a predetermined time is elapsed, the valve 264 is closed. Thus, the second gas whose flow rate is regulated by the MFC 263 is supplied to the substrates S in the process chamber 201 and is then exhausted. By supplying the second gas to the substrate S, it is possible to modify the first layer on the substrate S to a second layer. At this time, the valve 282 and the APC valve 283 are opened. In this case, the valve 268 may be opened to allow an inert gas to flow into the gas supply pipe 261 via the gas supply pipe 265. Also, the valves 258 and 254 may be opened to allow an inert gas to flow into the gas supply pipe 251.

### Purge Gas Supply Step S34

In the purge gas supply step S34, the process chamber 201 is purged according to the same procedure as in the purge gas supply step S32 described above.

### Performing a Predetermined Number of Times

A processing cycle that includes the first gas supply step S31, the purge gas supply step S32, the second gas supply step S33, and the purge gas supply step S34 is performed a predetermined number of times (n times where n is 1 or an integer of 2 or more). Thus, a film of a predetermined substance with a predetermined thickness, which contains, for example, the first element derived from the first gas and a second element derived from the second gas, is formed on the substrate S including the recess 700 on the surface.

### Pressure/Temperature Regulating Step S4

An inert gas is supplied as a purge gas into the process chamber 201 and exhausted through the exhaust pipe 281. Therefore, gases and reaction by-products remaining in the process chamber 201 are removed from the process chamber 201. Thereafter, an atmosphere inside the process chamber 201 is replaced with the inert gas, and the pressure inside the process chamber 201 is returned to normal pressure (atmospheric pressure restoration). In addition, the output of the heater 211 is controlled so that an interior of the process chamber 201 reaches a desired temperature (temperature regulation).

### Substrate Unloading Step S5

The vertical drive 400 lowers the base flange 401 to open the lower end of the reaction tube 210. The processed substrates S are then unloaded into the delivery chamber 217 while being supported by the substrate support 300 (boat unloading). The processed substrates S are unloaded from the substrate support 300 in the delivery chamber 217 (wafer discharging).

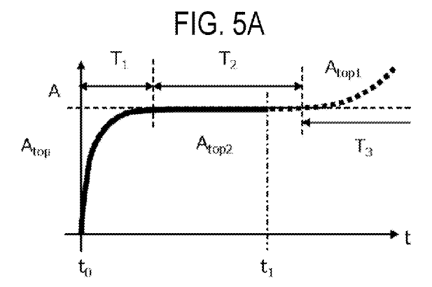

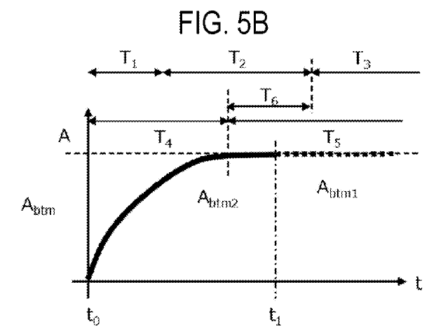

FIG. 5A is described in detail below.

The curve shown in FIG. 5A schematically shows a time-dependent change in an amount of the first substance deposited in the opening portion 701 (opening portion adsorption amount Aₜₒₚ) when the first gas is supplied to the substrate S under a predetermined condition that satisfies the first condition described below. The horizontal axis in FIG. 5A represents an elapsed time t from a first gas supply start time t₀. The vertical axis in FIG. 5A represents the amount Aₜₒₚ of the first substance deposited in the opening portion 701 per cycle. The first period T₁, the second period T₂, and the third period T₃ shown in FIG. 5A are described below.

The first period T₁ is a period after the supply of the first gas is started. During the first period T₁, many adsorption sites on which molecules of the first gas can be adsorbed (hereinafter simply referred to as adsorption sites) exist on the surface of the substrate S. Therefore, during the first period T₁, the Aₜₒₚ increases over time. Further, during the first period T₁, a decomposition rate of the first gas in the process chamber 201 is low (e.g., a low decomposition rate including 0 %). Therefore, most of the first gas adsorbed on the substrate S is undecomposed. As used herein, the decomposition rate of the first gas refers to an amount of the first gas decomposed in the process chamber 201 relative to a total amount of the first gas supplied into the process chamber 201.

The second period T₂ is a period after the first period T₁. During the second period T₂, the first gas is adsorbed on a majority of the adsorption sites on the substrate S. Further, during the second period T₂, the first gas supplied into the process chamber 201 and the first gas adsorbed on the substrate S are not decomposed. Therefore, the adsorption of the first gas on the substrate S is inhibited. Therefore, during the second period T₂, the Aₜₒₚ can be made to gradually approach a specific value (predetermined value A).

The third period T₃ is a period after the second period T₂. During the third period T₃, decomposition (thermal decomposition) of the first gas progresses. Substances (decomposition products of the first gas) produced by the decomposition of the first gas are more reactive than the undecomposed first gas. Therefore, adsorption of the decomposition products of the first gas on the substrate S is less likely to be inhibited by the first gas adsorbed on the substrate S. Accordingly, during the third period T₃, the Aₜₒₚ increases over time.

As described above, the Aₜₒₚ increases in the first period T₁, the Aₜₒₚ gradually approaches a predetermined value in the second period T₂, and the Aₜₒₚ increases in the third period T₃. In the present disclosure, a processing condition that is able to cause these phenomena is referred to as the first condition.

In the supply step S312, the first gas is supplied to the substrate S under a predetermined condition that satisfies the above-described temperature condition and the first condition. Then, in the supply step S312, the supply of the first gas is ended during the second period T₂ (specifically, at a time t₁ after a predetermined time is elapsed since the start of the supply of the first gas). The solid line Aₜₒₚ₂ shown in FIG. 5A indicates the Aₜₒₚ in the supply step S312. In contrast, the dashed line Aₜₒₚ₁ shown in FIG. 5A indicates the Aₜₒₚ in a case where the supply of the first gas is not ended during the second period T₂ and is continued during the third period T₃. The dashed line Aₜₒₚ₁ overlaps with the solid line Aₜₒₚ₂ during a period from the time t₀ to the time t₁ in FIG. 5A.

Next, FIG. 5B is described in detail.

The curve shown in FIG. 5B schematically shows a time-dependent change in an amount of the first substance deposited in the deep portion 702 (deep portion adsorption amount A_{btm}) when the first gas is supplied to the substrate S under a predetermined condition that satisfies the second and third conditions described below. The horizontal axis in FIG. 5B represents an elapsed time t from the first gas supply start time t₀. The vertical axis in FIG. 5B represents the amount A_{btm} of the first substance deposited in the deep portion 702 per cycle. Meanwhile, time scales of the Aₜₒₚ in FIG. 5A and the A_{btm} in FIG. 5B are assumed to be the same. FIG. 5B also shows the first period T₁, the second period T₂, and the third period T₃ in FIG. 5A. The fourth period T₄ and the fifth period T₅ shown in FIG. 5B are described below.

The fourth period T₄ is a period after the supply of the first gas is started. During the fourth period T₄, many adsorption sites for the first gas exist on the surface of the substrate S. Therefore, during the fourth period T₄, the A_{btm} increases over time. Meanwhile, during the fourth period T₄, the first gas more easily reaches the opening portion 701 than the deep portion 702. Thus, an increase curve of the A_{btm} during the fourth period T₄ is gentler than that of the Aₜₒₚ during the first period T₁. As a result, the fourth period T₄ ends after an end of the first period T₁.

The fifth period T₅ is a period after the fourth period T₄. During the fifth period T₅, the first gas is adsorbed on a majority of the adsorption sites on the substrate S. Further, during the fifth period T₅, the first gas supplied into the process chamber 201 and the first gas adsorbed on the substrate S are undecomposed, which inhibits adsorption of the first gas on the substrate S. Therefore, the A_{btm} can be made to gradually approach a specific value (predetermined value A) during the fifth period T₅. As shown in FIG. 5B, the fifth period T₅ is started after a start of the second period T₂ and before an end of the second period T₂. In other words, the second period T₂ and the fifth period T₅ at least partially overlap with each other. As shown in FIG. 5B, it is possible to reduce a difference between the Aₜₒₚ and the A_{btm} by providing a sixth period T₆ in which the second period T₂ and the fifth period T₅ overlap with each other, i.e., a sixth period T₆ in which both the Aₜₒₚ and the A_{btm} gradually approach the predetermined value A. Accordingly, it is possible to make a difference in thickness between films formed in the opening portion 701 and the deep portion 702 small, thereby improving step coverage.

As described above, the A_{btm} increases in the fourth period T₄, and the A_{btm} gradually approaches a predetermined value in the fifth period T₅. Further, the fifth period T₅ is started after the start of the second period T₂. In the present disclosure, a processing condition that causes these phenomena is referred to as the second condition.

As described above, the fifth period T₅ is started before the end of the second period T₂. In the present disclosure, a processing condition that causes this phenomenon is referred to as the third condition.

In the supply step S312, it is desirable to supply the first gas to the substrate S under a predetermined condition that satisfies the second condition and the third condition in addition to the temperature condition and the first condition described above. Further, in the supply step S312, it is more desirable to terminate the supply of the first gas to the substrate S during the sixth period T₆, which is a period in which the second period T₂ and the fifth period T₅ overlap with each other. The solid line A_{btm2} shown in FIG. 5B indicates the A_{btm} in the supply step S312, i.e., the A_{btm} when the supply of the first gas is ended during the sixth period T₆. In contrast, the dashed line Abₜₘ₁ shown in FIG. 5B indicates the A_{btm} when the supply of the first gas is not ended during the sixth period T₆ and the first gas is continuously supplied. The dashed line A_{btm1} overlaps with the solid line A_{btm2} during a period from the time t₀ to the time t₁ in FIG. 5B.

Meanwhile, as a ratio (aspect ratio) of a depth of the recess 700 to a width of the recess 700 increases, it becomes more difficult for the first gas to reach the deep portion 702. Therefore, a time difference between the start of the second period T₂ and the start of the fifth period T₅ tends to increase, which makes it difficult to satisfy the second condition. For example, when the aspect ratio of the recess 700 is 400 or more, the time difference between the start of the second period T₂ and the start of the fifth period T₅ tends to become large.

Herein, a case is considered where the processing step S3 is performed on a substrate S including a recess 700 with a high aspect ratio on the surface of the substrate S by setting the temperature of the substrate S to a temperature equal to or higher than the decomposition temperature of the first gas. In such a case, it is desirable to set the processing condition and the supply time t₁ in the processing step S3 so that a film with step coverage close to 100 % is formed in the recess 700. In this case, it may be said that there is almost no difference in film thickness between the opening portion 701 and the deep portion 702. Therefore, it is possible to determine whether the processing condition satisfies the first condition or the second condition, and to grasp the supply time t₁ such that the supply of the first gas to the substrate S is ended during the second period T₂ or the sixth period T₆. Accordingly, it is possible to form a film with good properties and step coverage.

Further, during the sixth period T₆, the Aₜₒₚ and the A_{btm} gradually approach the predetermined value A, which reduces the difference in thickness between the films formed in the opening portion 701 and the deep portion 702. Accordingly, by ending the supply of the first gas during the sixth period T₆, it is possible to further improve the step coverage.

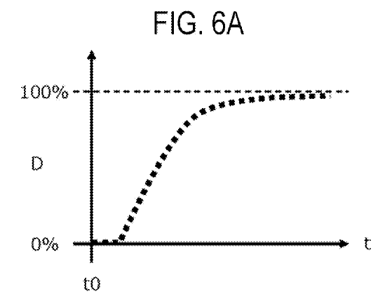

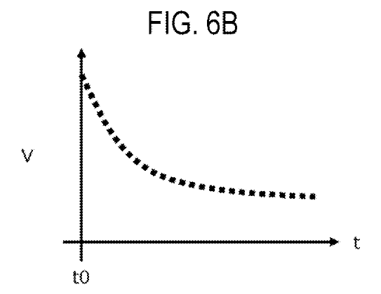

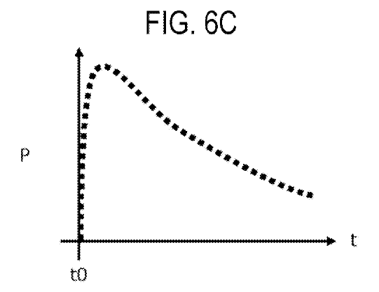

Hereinafter, the processing condition and the like in the supply step S312 is described with reference to FIGS. 6A, 6B and 6C.

FIG. 6A is a graph showing a change in the decomposition rate of the first gas in the process chamber 201 after the first gas is supplied. The horizontal axis in FIG. 6A represents the elapsed time t from the start of supply of the first gas. The vertical axis in FIG. 6A represents the decomposition rate D of the first gas in the process chamber 201. FIG. 6B is a graph showing a change in the flow velocity of the first gas in the process chamber 201 after the first gas is supplied. The horizontal axis in FIG. 6B represents the elapsed time t from the start of supply of the first gas. The vertical axis in FIG. 6B represents the flow velocity V of the first gas in the process chamber 201. FIG. 6C is a graph showing a change in the pressure inside the process chamber 201 after the first gas is supplied. The horizontal axis in FIG. 6C represents the elapsed time t from the start of supply of the first gas. The vertical axis in FIG. 6C represents the pressure (partial pressure of the first gas) P inside the process chamber 201.

In the supply step S312, the gas stored in the tank 259 is supplied into the process chamber 201, thereby supplying at least a portion of the first gas in the tank 259. As a result, a maximum supply amount may be made greater than a maximum exhaust amount.

As described above, the supply step S312 is performed under the temperature condition where the temperature of the substrate S (and the temperature inside the process chamber 201) is set to be equal to or higher than the decomposition temperature of the first gas. Therefore, as shown in FIG. 6A, the decomposition rate of the first gas in the process chamber 201 increases over time. At this time, as shown in FIG. 6A, it is desirable to maintain a low decomposition rate of the first gas in the process chamber 201 for a sufficient time (predetermined time) from the start of supply of the first gas until the predetermined time is elapsed. Therefore, it is possible to lengthen the second period T₂ and the fifth period T₅, and as a result, to lengthen the sixth period T₆. Accordingly, it is possible to improve the step coverage.

In the supply step S312, it is desirable to set the decomposition rate D to 0 % as shown in FIG. 6A during at least a portion of the period from the start to the end of the supply of the first gas to the substrate S. Therefore, it is possible to further lengthen the second period T₂ and the fifth period T₅, and as a result, to further lengthen the sixth period T₆. Accordingly, it is possible to further improve the step coverage.

As shown in FIG. 6B, in the supply step S312, the flow velocity V decreases over time from the start of supply of the first gas. The lower the flow velocity V, the longer the time (hereinafter referred to as a residence time) the first gas supplied into the process chamber 201 stays in the process chamber 201, which tends to increase the decomposition rate D. Therefore, as shown in FIG. 6B, it is desirable to maintain a high flow velocity V for a sufficient time (a predetermined time) and to maintain a short period of residence time for a sufficient time. Therefore, it is possible to further lengthen the second period T₂ and the fifth period T₅, and as a result, to further lengthen the sixth period T₆. Accordingly, it is possible to further improve the step coverage.

In the supply step S312, it is desirable to exhaust the process chamber 201 and shorten the residence time of the first gas. Further, it is desirable that the opening degree of the APC valve 283 is high, and it is more desirable that the APC valve 283 is fully opened. As a result, the flow velocity of the first gas in the process chamber 201 may be increased, thereby further suppressing the decomposition of the first gas.

Further, when the partial pressure of the first gas is high in the process chamber 201, the first gas is more likely to reach the deep portion 702. As shown in FIG. 6C, in the supply step S312, it is desirable to maintain the partial pressure of the first gas at a high level for a predetermined time from the start of the supply of the first gas. Therefore, it is possible to shorten the time from the start of the supply of the first gas to the start of the fifth period T₅, which makes it possible to sufficiently maintain the sixth period T₆. As a result, it is possible to further improve the step coverage.

In the supply step S312, it is desirable to set a maximum amount of the first gas supplied into the process chamber 201 per unit time (hereinafter referred to as a maximum supply amount) to be greater than a maximum amount of a gas exhausted from the process chamber 201 per unit time (hereinafter referred to as a maximum exhaust amount). This makes it easier to maintain a high partial pressure of the first gas in the process chamber 201.

As shown in FIG. 6C, in the supply step S312, it is desirable that the pressure P reaches a maximum value during a period from the start to the end of the supply of the first gas. Further, it is desirable that the pressure P at the time when the supply of the first gas is ended is at least half of the maximum value but less than the maximum value. Accordingly, it is possible to maintain a low decomposition rate of the first gas in the process chamber 201, which makes it possible to further improve the step coverage.

In the above-described substrate processing process, a thickness THKₜₒₚ₋ₙ of the film formed in the opening portion 701 is proportional to a thickness THKₜₒₚ of the film formed in the opening portion 701 in one processing cycle. Further, the THKₜₒₚ is proportional to the above-described Aₜₒₚ. From this, it may be noted that a graph of the elapsed time t and the THKₜₒₚ₋ₙ (hereinafter referred to as a first graph) created under a certain condition X exhibits a same shape as the graph of the Aₜₒₚ₁ shown in FIG. 5A. Therefore, if, as the elapsed time t increases, the first graph passes sequentially through a period in which the THKₜₒₚ₋ₙ increases, a period in which the THKₜₒₚ₋ₙ gradually approaches a predetermined value, and a period in which the THKₜₒₚ₋ₙ increases, it is possible to confirm that the condition X satisfies the first condition. In addition, it is possible to end the supply step S312 during the second period T₂ based on the first graph.

The same observation as in the first graph may be said for a graph (hereinafter referred to as a second graph) of the elapsed time t and a thickness THK_{btm-n} of the film formed in the deep portion 702 in the above-described substrate processing process. That is, by checking a shape of the second graph, it may be confirmed that the condition X satisfies the second condition, or the second and third conditions. In addition, it is possible to end the supply step S312 during the sixth period T₆ based on the first and second graphs.

From the above, the supply step S312 may be performed after a graph creation step S01 for creating the first graph and a condition setting step S02 for setting a time from the start to the end of the supply step S312 and a processing condition for the supply step S312 that satisfies the predetermined condition based on the first graph are performed as the preparation step S0, as shown in FIGS. 7A and 7D. Also, the first and second graphs may be created in the graph creation step S01, and the time from the start to the end of the supply step S312 and the processing condition for the supply step S312 that satisfies the predetermined condition may be set based on the first and second graphs in the condition setting step S02.

Specifically, as the graph creation step S01, a process may be performed that includes: step S011: supplying, under a test condition, the first gas to a substrate for testing (hereinafter referred to as a test substrate), including a recess for testing (hereinafter referred to as a test recess) on a surface of the test substrate, to form a film on the test recess; step S012: creating a first graph that is a graph of a first elapsed time which is a time that is elapsed since a start of step S011 and a thickness of a film formed at an opening portion of the test recess; and step S013: verifying, based on the first graph, that the test condition satisfies the first condition. The test condition may be used as the predetermined condition. Then, as the condition setting step S02, step S021: setting, based on the first graph, a time from the start to the end of the supply step S312 so that the supply step S312 is ended within the second period.

In the graph creation step S01, step S014: creating a second graph showing a relationship between the first elapsed time and a thickness of a film formed in a deep portion of the test recess, and step S015: verifying, based on the first and second graphs, that the test condition further satisfies the second condition may be further performed. In the graph creation step S01, step S016: verifying, based on the first and second graphs, that the test condition further satisfies the third condition may be further performed. Then, as the condition setting step S02, step S022: setting, based on the first and second graphs, a time from the start to the end of the supply step S312 so that the supply step S312 is ended within the sixth period.

Herein, it may be considered that in the supply step S312, the first gas is supplied to the opening portion 701 in approximately the same amount as that of the first gas supplied to a surface of a substrate including no recess on the surface of the substrate (hereinafter referred to as a flat substrate). Therefore, even when the flat substrate is used as the test substrate in the preparation step S0, it is possible to obtain the same effects as described above. Since the flat substrate is cheaper than a substrate with a recess formed on a surface of the substrate, cost incurred for the preparation step S0 may be reduced by using the flat substrate.

Shapes and opening directions of the test recess formed on the surface of the test substrate and the recess 700 formed on the surface of the substrate S may be different from each other. For example, the aspect ratios of the test recess and the recess 700 may be different from each other. In addition, for example, the test recess may be opened in a horizontal direction, and the recess 700 may be opened in a vertical direction. Even in these cases, it is possible to obtain at least some of the above-described effects.

The number of test recesses formed on one test substrate may be less than the number of recesses 700 formed on one substrate S. In this case, it is possible to reduce cost of the test substrate, making it possible to reduce the cost incurred for the preparation step S0. In addition, it is desirable that the aspect ratio of the test recess is equal to or greater than the aspect ratio of the recesses 700. In this case, it is easier to accurately grasp actual time-dependent changes in the Aₜₒₚ and the A_{btm} in the preparation step S0.

### 3 Effects of the Embodiments

The embodiments obtain one or more of the following effects.

a The supply step S312 is performed under the predetermined condition that satisfies the first condition described above and the temperature condition where the temperature of the substrate S is set to be equal to or higher than the decomposition temperature of the first gas. The supply step S312 is completed during the second period T₂. This makes it possible to improve at least one selected from the group of the film properties and the step coverage. This is described below.

By performing the supply step S312 under the above-described temperature condition, it is possible to improve the film properties. It is possible to desorb impurities derived from ligands of the first element in a molecular structure of the first gas from the substrate S. This makes it possible to improve the properties of the film formed on the substrate S. In addition, it is possible to suppress inhibition of reactions between the surface of the substrate S and various gases, which may otherwise be caused by the impurities. This makes it possible to improve productivity.

Further, by performing the supply step S312 under the above-described first condition and ending the supply step S312 (specifically, ending the supply of the first gas) during the second period T₂, it is possible to improve the step coverage. This is because, during the second period T₂, the Aₜₒₚ may be made to gradually approach the predetermined value A, thereby promoting an increase in the film thickness of the deep portion 702 while suppressing an increase in the film thickness of the opening portion 701. Therefore, by ending the supply of the first gas during the second period T₂, it is possible to improve the step coverage. During the first period T₁, the first gas is less likely to reach the deep portion 702 than the opening portion 701, and therefore, the increase in the film thickness of the deep portion 702 proceeds more slowly than the increase in the film thickness of the opening portion 701. During the third period T₃, the decomposition of the first gas proceeds, promoting an increase in the film thickness of the opening portion 701. Therefore, if the supply of the first gas is ended during the first period T₁ or the third period T₃, it is difficult to improve the step coverage.

In general, when the temperature of the substrate S is set to be equal to or higher than the thermal decomposition temperature of the first gas, the decomposition products of the first gas are more likely to be supplied to the opening portion 701. Therefore, the Aₜₒₚ is more likely to increase, making it difficult to improve the step coverage. According to the technique of the present disclosure, it is possible to improve the step coverage even when the temperature of the substrate S is set to the thermal decomposition temperature of the first gas or higher. In other words, it is possible to simultaneously achieve improvement in the film properties and/or the productivity and improvement in the step coverage.

b Further, by performing the supply step S312 under the predetermined condition that satisfies the second condition described above, it is possible to reduce the difference in film thickness between the opening portion 701 and the deep portion 702, thereby further improving the step coverage.

c Further, by performing the supply step S312 under the predetermined condition that satisfies the third condition described above, it is possible to further reduce the difference in film thickness between the opening portion 701 and the deep portion 702, thereby further improving the step coverage.

d By ending the supply of the first gas to the substrate S during the sixth period T₆ in which the second period T₂ and the fifth period T₅ overlap with each other, it is possible to end the supply step S312 while maintaining a small difference in film thickness between the opening portion 701 and the deep portion 702. This makes it possible to further improve the step coverage.

e By setting the decomposition rate of the first gas in the process chamber 201 to 0 % during at least a part of the supply time, which is the time from the start to the end of the supply of the first gas to the substrate S, it is possible to lengthen the second period T₂, making it possible to sufficiently secure the sixth period T₆. As a result, it is possible to further improve the step coverage.

Meanwhile, when the supply step S312 is performed under a condition in which the sixth period does not exist, a relationship of A_{btm} < Aₜₒₚ always holds regardless of the time at which the supply of the first gas is ended. Further, when the supply of the first gas is ended before the start of the sixth period, a relationship of A_{btm} < A = Aₜₒₚ holds, and when the supply of the first gas is ended after the end of the sixth period, a relationship of A_{btm} = A < Aₜₒₚ holds. That is, in these cases, the step coverage is likely to decrease.

f The above-described cycle includes the first gas supply step S31 in which the first gas is stored in the tank 259. In the supply step S312, at least a portion of the first gas stored in the tank 259 in the first gas supply step S31 is supplied to the substrate S. This makes it possible to further improve the step coverage.

g In the supply step S312, the pressure in the process chamber 201 reaches a maximum value during a period from the start to the end of the supply of the first gas, thereby maintaining a low decomposition rate of the first gas in the process chamber 201. This makes it possible to further improve the step coverage.

h In the supply step S312, the pressure inside the process chamber 201 at the time at which the supply of the first gas is ended is set to at least half of the maximum value but not more than the maximum value, thereby maintaining a low decomposition rate of the first gas inside the process chamber 201. This makes it possible to further improve the step coverage.

Although the embodiments of the present disclosure are specifically described above, the present disclosure is not limited thereto, and various modifications may be made without departing from the spirit of the present disclosure.

The first gas may be, for example, predetermined element-containing gases that contain a predetermined element (first element) such as tungsten (W), titanium (Ti), molybdenum (Mo), tantalum (Ta), cobalt (Co), yttrium (Y), ruthenium (Ru), hafnium (Hf), zirconium (Zr), aluminum (Al), or silicon (Si). One or more of these gases may be used as the first gas. Gases obtained by activating these gases with plasma or the like may also be used as the first gas.

The predetermined element-containing gases may be, for example, halogen-based predetermined element-containing gases containing a predetermined element and a halogen element. Examples of the halogen-based predetermined element-containing gases may be gases including hexachlorotungsten (WCl₆), hexafluorotungsten (WF₆), titanium tetrachloride (TiCl₄), titanium tetrafluoride (TiF₄), molybdenum pentachloride (MoCl₅), molybdenum pentafluoride (MoF₅), molybdenum dioxide dichloride (MoO₂Cl₂), molybdenum oxide tetrachloride (MoOCl₄), tantalum pentachloride (TaCl₅), tantalum pentafluoride (TaF₅), cobalt difluoride (CoF₂), cobalt dichloride (CoCl₂), yttrium trifluoride (YF₃), yttrium trichloride (YCl₃), ruthenium trichloride (RuCl₃), ruthenium trifluoride (RuF₃), hafnium tetrachloride (HfCl₄), hafnium tetrafluoride (HfF₄), zirconium tetrachloride (ZrCl₄), zirconium tetrafluoride (ZrF₄), aluminum trichloride (AlCl₃), aluminum trifluoride (AlF₃), dichlorosilane (SiH₂Cl₂), 1,2-dichlorodisilane (Si₂H₄Cl₂), 1,1,1-trichlorodisilane (Si₂H₃Cl₃), 1,1,2-trichlorodisilane (Si₂H₃Cl₃), pentachlorodisilane (Si₂HCl₅), hexachlorodisilane (Si₂Cl₆), tetrafluorosilane (SiF₄), and the like. In addition, the predetermined element-containing gases may be, for example, gases including monosilane (SiH₄), disilane (Si₂H₆), trisilane (Si₃H₈), tetrasilane (Si₄H₁₀), and the like. One or more of these gases may be used as the predetermined element-containing gases.

The predetermined element-containing gases may be, for example, organic predetermined element-containing gases containing a predetermined element and an organic ligand. Examples of the organic predetermined element-containing gases may be gases including hexadimethylaminoditungsten (W₂[N(CH₃)₂]₆), bis(tertiary-butylimido)bis(dimethylamido)tungsten ((t-C₄H₉N=)₂W(N(CH₃)₂)₂), tetrakis(ethylmethylamino)titanium (Ti[N(C₂H₅)(CH₃)]₄), bis(ethylcyclopentadienyl)ruthenium (Ru(EtCp)₂), bis(cyclopentadienyl)ruthenium (Ru(Cp)₂), tetrakis(ethylmethylamino)hafnium (Hf[N(Me)Et]₄), tetrakis(diethylamino)hafnium (Hf[N(Et)₂]₄), tetrakis(dimethylamino)hafnium (Hf[N(Me)₂]₄), trisdimethylaminocyclopentadienyl hafnium ((Cp)Hf[N(Me)₂]₃), tetrakisethylmethylaminozirconium (Zr[N(Me)Et]₄), tetrakisdiethylaminozirconium (Zr[N(Et)₂]₄), tetrakisdimethylaminozirconium (Zr[N(Me)₂]₄), trisdimethylaminocyclopentadienyl zirconium ((Cp)Zr[N(Me)₂]₃), trimethylaluminum (Al(CH₃)₃), trisdimethylaminosilane (Si[N(CH₃)₂]₃H), and the like. One or more of these gases may be used as the predetermined element-containing gases.

When a gas containing two or more atoms of a predetermined element in its molecular structure is used as the first gas, thermal decomposition of the first gas tends to generate highly reactive products containing the predetermined element. This tends to increase the film thickness near the opening portion 701, which may result in a decrease in the step coverage. According to the technique of the present disclosure, even in such cases, it is possible to improve the step coverage. As the gases containing two or more atoms of a predetermined element, for example, one or more gases including Si₂H₄Cl₂, Si₂H₃Cl₃, Si₂H₃Cl₃, Si₂HCl₅, Si₂Cl₆, Si₂H₆, Si₃H₈, Si₄H₁₀, W₂[N(CH₃)₂]₆, and the like may be used.

The second gas may be, for example, gases including a reducing gas, an oxidizing gas, a nitriding gas, a sulfiding gas, a selenizing e gas, a tellurizing gas, and the like. One or more of these gases may be used as the second gas. Gases obtained by activating these gases with plasma or the like may also be used as the second gas. For example, when the first gas is a gas containing a predetermined element and the second gas is a reducing gas, a film composed of a single predetermined element may be formed on the substrate S. Further, when the first gas is a gas containing a predetermined element and the second gas is any one of an oxidizing gas, a nitriding gas, a sulfiding gas, a selenizing gas and a tellurizing gas, an oxide film of the predetermined element, a nitride film of the predetermined element, a sulfide film of the predetermined element, a selenide film of the predetermined element, or a telluride film of the predetermined element may be formed on the substrate S.

As the reducing gas, for example, one or more of gases including a hydrogen (H₂) gas, a deuterium (D₂) gas, a borane (BH₃) gas, a diborane (B₂H₆) gas, a carbon monoxide (CO) gas, an ammonia (NH₃) gas, a monosilane (SiH₄) gas, a disilane (Si₂H₆) gas, a trisilane (Si₃H₈) gas, a monogermane (GeH₄) gas, a digermane (Ge₂H₆), and the like may be used. As the oxidizing gas, for example, one or more gases including oxygen (O₂), ozone (O₃), water vapor (H₂O), a mixed gas of H₂ and O₂, hydrogen peroxide (H₂O₂), nitrous oxide (N₂O), and the like may be used. As the nitriding gas, for example, one or more of hydrogen nitride-based gases such as an ammonia (NH₃) gas, a diazene (N₂H₂) gas, a hydrazine (N₂H₄) gas, an N₃H₈ gas, and the like may be used. As the sulfiding gas, for example, gases including sulfane (H₂S), disulfane (H₂S₂), diammonium sulfide ((NH₄)₂S), dimethyl sulfide ((CH₃)₂S), and the like may be used. One or more of these gases may be used as the sulfiding gas. As the selenizing gas, for example, gases including selane (H₂Se), diselane (H₂Se₂), dimethyl selenide ((CH₃)₂Se), and the like may be used. One or more of these gases may be used as the selenizing gas. As the tellurizing gas, for example, gases including tellane (H₂Te), ditellane (H₂Te₂), dimethyl telluride ((CH₃)₂Te), and the like may be used. One or more of these gases may be used as the tellurizing gas.

The inert gas may be, for example, rare gases such as a helium (He) gas, an argon (Ar) gas, a neon (Ne) gas, a xenon (Xe) gas and the like, or a nitrogen (N₂) gas. One or more of these gases may be used as the inert gas.

In the above-described embodiments, the case where the film is formed on the substrate S by using the first gas and the second gas in the processing step S3 is described by way of example. However, the technique of the present disclosure is not limited thereto. For example, the technique of the present disclosure may be applied even when three or more types of gas are used. In addition, for example, the technique of the present disclosure may be applied even when the second gas supply step S33 and the purge gas supply step S34 are omitted.

In the above-described embodiments, the example in which the film is formed by using the batch-type substrate processing apparatus that processes a plurality of substrates at a time is described. The present disclosure is not limited to the above-described embodiments and may be suitably applied to, for example, a case where a film is formed by using a single-substrate-type substrate processing apparatus that processes one or several substrates at a time. Further, in the above-described embodiments, the example in which the film is formed by using the substrate processing apparatus including the hot-wall-type process furnace is described. The present disclosure is not limited to the above-described embodiments and may be suitably applied to a case where a film is formed by using a substrate processing apparatus including a cold-wall-type process furnace. The same effects as those of the above-described embodiments and modifications may be obtained.

The above-described embodiments and modifications may be used in appropriate combinations, and the processing procedures and conditions in such combinations may be the same as those of the above-described embodiments and modifications.

According to the present disclosure in some embodiments, it is possible to improve at least one selected from the group of film properties and step coverage.

While certain embodiments are described, these embodiments are presented by way of example, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
forming a film of a predetermined substance containing a first element by performing a cycle a predetermined number of times, the cycle including:
(a1) supplying, under a predetermined condition, a first gas to the substrate, which includes a recess on a surface of the substrate, to deposit a first substance containing the first element on the surface of the substrate,
wherein the predetermined condition satisfies:
a temperature condition that a temperature of the substrate is set to be equal to or higher than a decomposition temperature of the first gas, and
a first condition that an opening portion adsorption amount, which is an amount of the first substance adsorbed on an opening portion of the recess, increases during a first period after a start of the supply of the first gas, the opening portion adsorption amount gradually approaches a predetermined value during a second period after the first period, and the opening portion adsorption amount increases during a third period after the second period, and
wherein (a1) is ended during the second period.

2. The method of claim 1, wherein the predetermined condition further satisfies a second condition that a deep portion adsorption amount, which is an amount of the first substance adsorbed on a deep portion of the recess, increases during a fourth period after the start of the supply of the first gas, the deep portion adsorption amount gradually approaches the predetermined value during a fifth period after the fourth period, and the fifth period is started after a start of the second period.

3. The method of claim 2, wherein the predetermined condition further satisfies a third condition that the fifth period is started before an end of the second period.

4. The method of claim 3, wherein in (a1), the supply of the first gas to the substrate is ended during a sixth period in which the second period and the fifth period overlap with each other.

5. The method of claim 1, wherein in (a1), a decomposition rate of the first gas in a space where the substrate exists is set to 0% during at least a part of a supply time from the start to an end of the supply of the first gas to the substrate.

6. The method of claim 1, wherein the cycle further includes (a0) storing the first gas in a storage, and
wherein in (a1), at least a portion of the first gas stored in the storage in (a0) is supplied to the substrate.

7. The method of claim 1, wherein in (a1), a pressure in a space where the substrate exists reaches a maximum value during a period from the start to an end of the supply of the first gas.

8. The method of claim 7, wherein in (a1), the pressure in the space at a time at which the supply of the first gas is ended is set to at least half of the maximum value but not more than the maximum value.

9. The method of claim 1, wherein the cycle further includes (b) supplying a second gas, which modifies the first substance, to the substrate.

10. The method of claim 1, wherein the first gas is a gas containing two or more atoms of a predetermined element in a molecular structure of the first gas.

11. The method of claim 4, further comprising:
(c) which includes:
(c1) supplying, under a test condition, the first gas to a test substrate, which includes a test recess on a surface of the test substrate, to form the film on the test recess;
(c2) creating a first graph, which is a graph of a first elapsed time elapsed since a start of (c1) and a thickness of the film formed at an opening portion of the test recess; and
(c3) verifying, based on the first graph, that the test condition satisfies the first condition; and
(d1) setting a time from starting (a1) to ending (a1) based on the first graph so that (a1) is ended during the second period,
wherein the test condition is used as the predetermined condition.

12. The method of claim 11, wherein (c) further includes:
(c4) creating a second graph showing a relationship between the first elapsed time and a thickness of the film formed at a deep portion of the test recess; and
(c5) verifying, based on the first graph and the second graph, that the test condition further satisfies the second condition and the third condition, and
wherein the method further comprises:
(d2) setting the time from starting (a1) to ending (a1) based on the first graph and the second graph so that (a1) is ended during the sixth period.

13. The method of claim 1, further comprising:
(e) which includes:
(e1) supplying, under a test condition, the first gas to a test substrate to form the film on the test substrate;
(e2) creating a first graph showing a relationship between a first elapsed time elapsed since a start of (e1) and a thickness of the film formed on the test substrate; and
(e3) verifying, based on the first graph, that the test condition satisfies the first condition; and
(f) setting a time from starting (a1) to ending (a1) based on the first graph so that (a1) is ended during the second period,
wherein the test condition is used as the predetermined condition.

14. The method of claim 1, wherein (a1) includes a period in which a decomposition rate of the first gas in a space where the substrate exists increases over time.

15. The method of claim 1, wherein (a1) includes a period in which a flow velocity of the first gas in a space where the substrate exists decreases over time.

16. The method of claim 1, wherein a maximum amount of the first gas supplied per unit time into a space where the substrate exists in (a1) is larger than a maximum amount of a gas exhausted per unit time from the space in (a1).

17. A method of manufacturing a semiconductor device comprising the method of claim 1.

18. A substrate processing apparatus, comprising:
a first gas supply system configured to supply a first gas to a substrate including a recess on a surface of the substrate;
a temperature controller configured to control a temperature of the substrate; and
a controller configured to be capable of controlling the first gas supply system and the temperature controller so as to form a film of a predetermined substance containing a first element by performing a cycle a predetermined number of times, the cycle including:
(a1) supplying, under a predetermined condition, the first gas to the substrate to deposit a first substance containing the first element on the surface of the substrate,
wherein the predetermined condition satisfies:
a temperature condition that the temperature of the substrate is set to be equal to or higher than a decomposition temperature of the first gas, and
a first condition that an opening portion adsorption amount, which is an amount of the first substance adsorbed on an opening portion of the recess, increases during a first period after a start of the supply of the first gas, the opening portion adsorption amount gradually approaches a predetermined value during a second period after the first period, and the opening portion adsorption amount increases during a third period after the second period, and
wherein (a1) is ended during the second period.

19. A non-transitory computer-readable recording medium storing a program that causes, by a computer, a substrate processing apparatus to perform:
forming a film of a predetermined substance containing a first element by performing a cycle a predetermined number of times, the cycle including:
(a1) supplying, under a predetermined condition, a first gas to a substrate, which includes a recess on a surface of the substrate, to deposit a first substance containing the first element on the surface of the substrate,
wherein the predetermined condition satisfies:
a temperature condition that a temperature of the substrate is set to be equal to or higher than a decomposition temperature of the first gas, and
a first condition that an opening portion adsorption amount, which is an amount of the first substance adsorbed on an opening portion of the recess, increases during a first period after a start of the supply of the first gas, the opening portion adsorption amount gradually approaches a predetermined value during a second period after the first period, and the opening portion adsorption amount increases during a third period after the second period, and
wherein (a1) is ended during the second period.
